(19) United States
(12) Patent Application Publication
(10) Pub. No.: US 2026/0129887 A1
(43) Pub. Date: May 7, 2026

(54) SEMICONDUCTOR STRUCTURE HAVING CAPACITOR AND METHOD OF MANUFACTURING THEREOF

(71) Applicant: TAIWAN SEMICONDUCTOR MANUFACTURING COMPANY LTD., HSINCHU (TW)

(72) Inventor: HUNG-TE LIN, HSINCHU COUNTY (TW)

(21) Appl. No.: 18/938,327

(22) Filed: Nov. 6, 2024

(51) Int. Cl. H01L 21/762; H01L 27/06

(52) U.S. Cl. CPC H10D 1/714; H10D 84/811; H10W 10/014; H10W 10/17

(57) ABSTRACT

A semiconductor structure includes a substrate having a surface, and a capacitor structure disposed within the substrate and having a bottom portion, a sidewall portion disposed over and coupled to the bottom portion, and an upper portion coupled to the sidewall portion and exposed through the surface. The semiconductor structure further includes a semiconductor device disposed over and separated from the capacitor structure. The sidewall portion is disposed between the bottom portion and the upper portion, and at least a portion of the semiconductor device is surrounded by the sidewall portion of the capacitor structure from a plan view.

### BACKGROUND

The semiconductor industry has experienced rapid growth due to ongoing improvements in integration density of a variety of electrical components. To accommodate the miniaturized scale of semiconductor devices, various technologies and applications have been developed for wafer-level packaging, involving greater numbers of different components with different functions. Improvements in integration density have resulted from iterative reduction of minimum feature size, allowing more components to be integrated into a given area. Such advances require the semiconductor devices to undergo ever-greater numbers of manufacturing processes.

As semiconductor technologies further advance, embedding of electrical components into a semiconductive substrate has emerged as an effective approach to further reducing a physical size of a semiconductor device. The electrical component is at least partially embedded within the semiconductive substrate in order to minimize an amount of space occupied above the semiconductive substrate. Such embedding processes utilize sophisticated techniques, and improvements are desired.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a semiconductor structure in accordance with some embodiments of the present disclosure.

FIG. 2 is a schematic top view of a semiconductor structure in accordance with some embodiments of the present disclosure.

FIG. 3 is a schematic cross-sectional view taken along a line A-A′ in FIG. 1 or FIG. 2.

FIG. 4 is a cross-sectional view of a semiconductor structure in accordance with some embodiments of the present disclosure.

FIG. 5 is a schematic top view of a semiconductor structure in accordance with some embodiments of the present disclosure.

FIG. 6 is a schematic cross-sectional view taken along a line B-B′ in FIG. 5.

FIG. 7A is a schematic cross-sectional view of a semiconductor structure according to aspects of the present disclosure in some embodiments.

FIGS. 7B, 8 and 9 are schematic top views of a semiconductor structure in accordance with some embodiments of the present disclosure.

FIG. 10 is a cross-sectional view of a semiconductor structure in accordance with some embodiments of the present disclosure.

FIG. 11 is a flow diagram of a method of manufacturing a semiconductor structure in accordance with some embodiments of the present disclosure.

FIG. 12 is a flow diagram of a method of manufacturing a semiconductor structure in accordance with some embodiments of the present disclosure.

FIGS. 13 to 31 are cross-sectional views of one or more stages of a method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal variation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In the present disclosure, a semiconductor structure and a method of manufacturing a semiconductor structure are provided. The semiconductor structure includes a substrate, a capacitor structure disposed within the substrate and having a bottom portion and a sidewall portion disposed over and coupled to the bottom portion, an isolation layer disposed over the capacitor structure and within the substrate, and a semiconductor device disposed over the isolation layer and including an oxide layer disposed over a first surface of the substrate. The isolation layer is enclosed by the oxide layer and the capacitor structure, at least a portion of the semiconductor device is surrounded by the sidewall portion of the capacitor structure, and the semiconductor device is separated from the capacitor structure. An overall component density of the semiconductor structure can therefore be increased or improved.

In some embodiments, a method of manufacturing a semiconductor structure includes providing a substrate having a first surface; forming a recess in the substrate on the first surface; forming a capacitor structure within and conformal to the recess; forming an isolation layer in the recess and over the capacitor structure; disposing a semiconductor material layer in the recess and over the isolation layer; and forming a semiconductor device over the semiconductor material layer. At least a portion of the semiconductor device is surrounded by the capacitor structure.

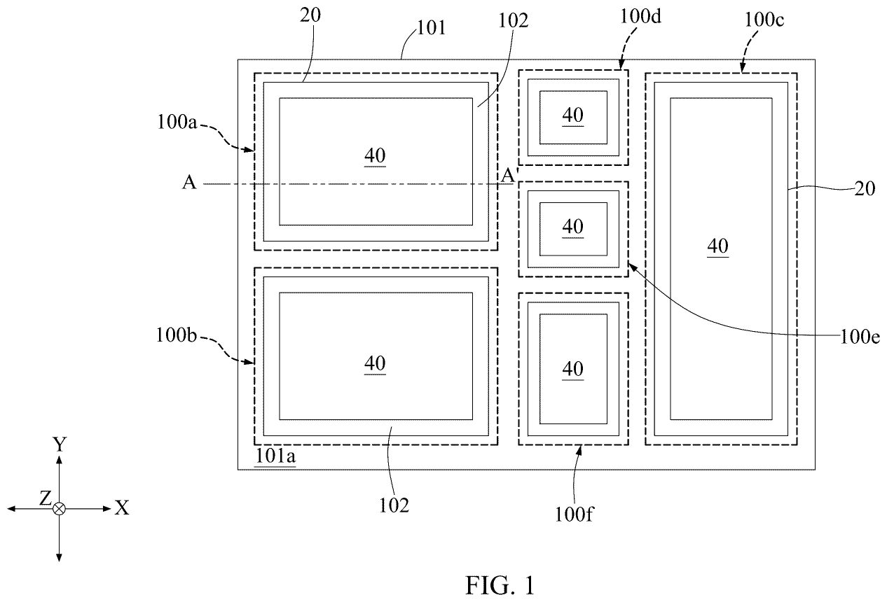

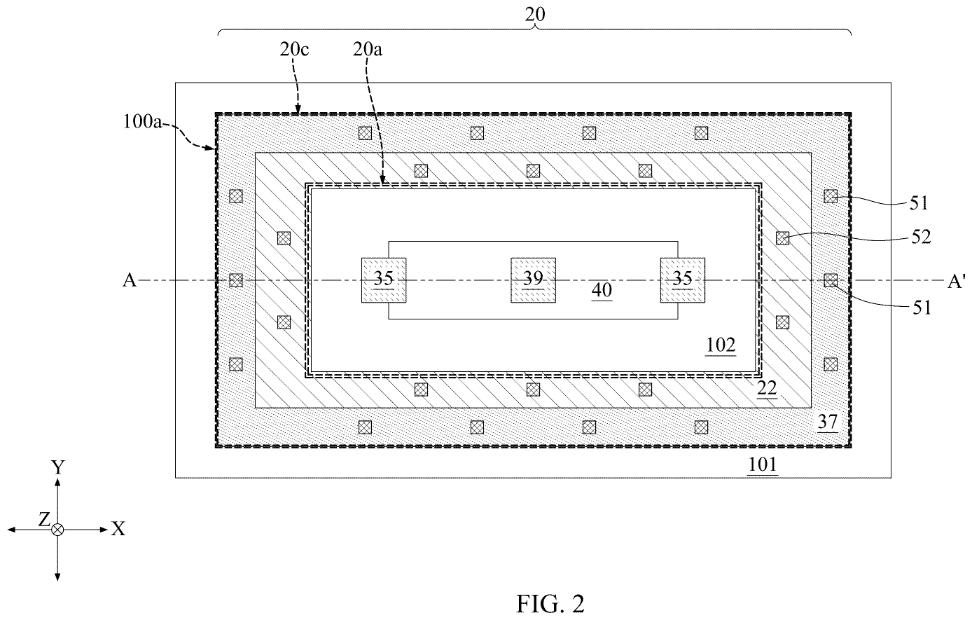

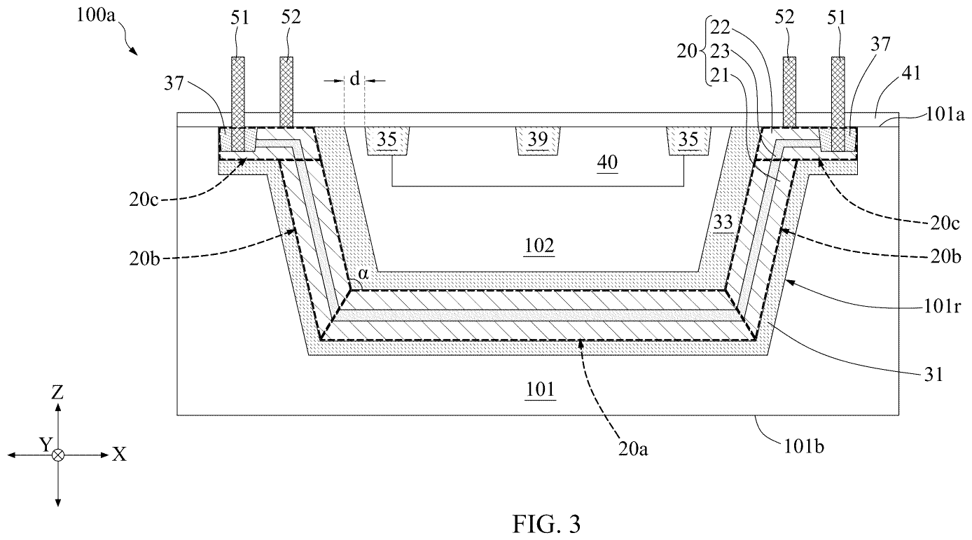

FIG. 1 is a schematic top view of a semiconductor structure according to aspects of the present disclosure in some embodiments. FIG. 2 is a schematic top view of a semiconductor structure according to aspects of the present disclosure in some embodiments. FIG. 3 is a schematic cross-sectional view taken along a line A-A′ in FIG. 1 or FIG. 2. Referring to FIGS. 1, 2 and 3, a plurality of semiconductor structures 100a, 100b, 100c, 100d, 100e and 100f are disposed on a first surface 101a of a substrate 101, and each of the semiconductor structures 100a, 100b, 100c, 100d, 100e and 100f includes at least one semiconductor device 40. A plurality of capacitor structures 20 are disposed on the first surface 101a of the substrate 101. In some embodiments, the semiconductor structure 100a is a chip, a package or a part of a chip or a package. In some embodiments, the semiconductor structure 100a is a part of a system on integrated circuit (SoIC) structure, a chip on wafer on substrate (CoWoS) structure, an integrated fan out (InFO) structure, or the like.

The semiconductor structure 100a includes the substrate 101. In some embodiments, the substrate 101 is a part of a substrate comprising at least one of an epitaxial layer, a single crystalline semiconductor material such as, but not limited to, at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the substrate 101 is a semiconductor wafer. In some embodiments, the substrate 101 comprises at least one of crystalline silicon and other suitable materials. Other structures and/or configurations of the substrate 101 are within the scope of the present disclosure.

The substrate 101 includes the first surface 101a and a second surface 101b opposite to the first surface 101a. In some embodiments, the first surface 101a is a front side or an active side with several electrical components disposed thereon. In some embodiments, the second surface 101b is a back side or an inactive side from which electrical components are absent.

In some embodiments, the semiconductor structure 100a includes one of the capacitor structures 20 and one of the semiconductor devices 40 disposed above and electrically isolated from the capacitor structure 20. In some embodiments, each of the plurality of semiconductor structures 100a, 100b, 100c, 100d, 100e and 100f may include one of the capacitor structures 20 and one of the semiconductor devices 40 disposed over the corresponding capacitor structure 20. The capacitor structure 20 is disposed within the substrate 101. In some embodiments, the capacitor structure 20 is configured to provide capacitance for a circuitry in the substrate 101.

The capacitor structure 20 is disposed under the semiconductor device 40 and includes a bottom portion 20a and a sidewall portion 20b disposed over and coupled to the bottom portion 20a. In some embodiments, the bottom portion 20a extends along a first direction X parallel to the first surface 101a. The bottom portion 20a extends in the horizontal plane (i.e., the X-Y plane as shown in FIG. 2). The bottom portion 20a is disposed under the semiconductor device 40. In some embodiments, the bottom portion 20a has a rectangular shape. Although the bottom portion 20a of the capacitor structure 20 is shown as being rectangular in FIG. 2, in other embodiments the bottom portion 20a can comprise other shapes, such as hexagon, octagon, circle, or others. In some embodiments, the sidewall portion 20b encircles the bottom portion 20a.

The sidewall portion 20b extends upward from a perimeter of the bottom portion 20a and toward the first surface 101a of the semiconductor substrate 101. In some embodiments, the sidewall portion 20b reaches the first surface 101a of the semiconductor substrate 101. In some embodiments, the sidewall portion 20b extends upward from two opposite sides of the bottom portion 20a. In some embodiments, the sidewall portion 20b extends upward from an entirety of the perimeter of the bottom portion 20a, and the sidewall portion 20b surrounds the semiconductor device 40 from a plan view. The sidewall portion 20b is oriented at an angle α respective to the plane of the bottom portion 20a, as shown in FIG. 3. In some embodiments, the angle α between the bottom portion 20a and sidewall portion 20b is close to 90°. In some embodiments, the sidewall portion 20b is at an obtuse angle respective to the bottom portion 20a, that is, the angle α is greater than 90°. An acute angle (i.e., an angle less than 90°) is also contemplated for the angle α. In some embodiments, the sidewall portion 20b is at an angle of between 85° and 160° respective to the plane of the bottom portion 20a. Formation of the sidewall portion 20b may be difficult if the angle α is too small. The capacitor structure 20 may occupy too much area if the angle α is too large. It should also be noted that the sidewall portion 20b may not be perfectly straight, e.g., the sidewall portion 20b may have some curvature (not shown). Likewise, while the bottom portion 20a is illustrated as being planar, some curvature to the bottom portion 20a may also be present in some embodiments.

In some embodiments, the capacitor structure 20 further includes an upper portion 20c coupled to the sidewall portion 20b. The sidewall portion 20b is disposed between the bottom portion 20a and the upper portion 20c, and the upper portion 20c is in contact with a dielectric layer, such as an oxide layer 41 disposed on the first surface 101a. In some embodiments, the upper portion 20c extends from the sidewall portion 20b and away from the semiconductor device 40 along the first direction X. In some embodiments, a top surface of the upper portion 20c is coplanar with the first surface 101a. In some embodiments, the upper portion 20c encircles the bottom portion 20a from a plan view.

In some embodiments, the bottom portion 20a and the sidewall portion 20b are integral and continuous, and an interface between the bottom portion 20a and the sidewall portion 20b is absent. In some embodiments, the bottom portion 20a, the sidewall portion 20b and the upper portion 20c are integral and continuous.

In some embodiments, a first isolation layer 31 is disposed under the capacitor structure 20, and a second isolation layer 33 is disposed over the capacitor structure 20 and between the capacitor structure 20 and the semiconductor device 40. The capacitor structure 20 is disposed between the first isolation layer 31 and the second isolation layer 33.

In some embodiments, the first isolation layer 31 is disposed between the capacitor structure 20 and the substrate 101, such that the capacitor structure 20 is electrically isolated from the substrate 101 by the first isolation layer 31. The first isolation layer 31 includes a dielectric material such as oxide or the like. In some embodiments, the first isolation layer 31 includes silicon dioxide or the like. In some embodiments, the first isolation layer 31 includes a high-k (high dielectric constant) dielectric material, such as hafnium aluminum oxide (HfAlO), zirconium dioxide (ZrO₂), aluminum oxide, titanium oxide, or the like.

The second isolation layer 33 is disposed over the capacitor structure 20. In some embodiments, the second isolation layer 33 entirely covers and is in contact with the bottom portion 20a and the sidewall portion 20b of the capacitor structure 20, such that the capacitor structure 20 is electrically isolated from the semiconductor device 40 by the second isolation layer 33. The second isolation layer 33 is conformal to the capacitor structure 20. The second isolation layer 33 is enclosed by the oxide layer 41 and the capacitor structure 20. In some embodiments, a peripheral portion of the second isolation layer 33 is coplanar with the first surface 101a of the substrate 101.

The second isolation layer 33 includes a dielectric material such as oxide or the like. In some embodiments, the second isolation layer 33 includes silicon dioxide or the like. In some embodiments, the second isolation layer 33 includes high-k (high dielectric constant) dielectric material, such as HfAlO, ZrO₂, aluminum oxide, titanium oxide, or the like. In some embodiments, the second isolation layer 33 and the first isolation layer 31 include a same material.

In some embodiments, the capacitor structure 20 includes a first electrode layer 21, a second electrode layer 22 over the first electrode layer, and a dielectric 23 between the first electrode layer 21 and the second electrode layer 22. In some embodiments, the first electrode layer 21, the dielectric 23, and the second electrode layer 22 are sequentially stacked. In some embodiments, the capacitor structure 20 includes several first electrode layers 21, several dielectrics 23, and several second electrode layers 22 alternately stacked between the first isolation layer 31 and the second isolation layer 33.

The first electrode layer 21 is disposed over and conformal to the first isolation layer 31. In some embodiments, the first electrode layer 21 is disposed in the bottom portion 20a, the sidewall portion 20b and the upper portion 20c of the capacitor structure 20. In some embodiments, the first electrode layer 21 is integral and continuous. In some embodiments, a periphery of the first electrode layer 21 is in contact with the substrate 101. The first electrode layer 21may include a conductive material such as cobalt, titanium nitride (TiN), metal silicide, polysilicon, or the like. In some embodiments, the first electrode layer 21 is a bottom electrode of the capacitor structure 20. In some embodiments, the first electrode layer 21 includes nickel silicide (NiSi) or cobalt silicide (CoSi).

The dielectric 23 is disposed over and conformal to the first electrode layer 21. In some embodiments, the dielectric 23 is disposed in the bottom portion 20a, the sidewall portion 20b and the upper portion 20c of the capacitor structure 20. In some embodiments, the dielectric 23 is integral and continuous. In some embodiments, the first electrode layer 21 is enclosed by and in contact with the dielectric 23 and the first isolation layer 31. In some embodiments, a periphery of the dielectric 23 is in contact with the substrate 101.

The dielectric 23 includes a dielectric material such as nitride, oxide or the like. In some embodiments, the dielectric 23 includes a high-k dielectric material, such as HfAlO, ZrO₂, aluminum oxide, titanium oxide, or the like.

The second electrode layer 22 is disposed over and conformal to the dielectric 23. In some embodiments, the second electrode layer 22 covers the dielectric 23. In some embodiments, the second electrode layer 22 is disposed in the bottom portion 20a, the sidewall portion 20b and the upper portion 20c of the capacitor structure 20. In some embodiments, a portion of the second electrode layer 22 disposed within the upper portion 20c is coplanar with the first surface 101a. In some embodiments, the second electrode layer 22 is integral and continuous. In some embodiments, the dielectric 23 is enclosed by the first electrode layer 21 and the second electrode layer 22, and the second electrode layer 22 is disposed between the dielectric 23 and the second isolation layer 33.

In some embodiments, the second electrode layer 22 is a top electrode of the capacitor structure 20. The second electrode layer 22 may include a conductive material such as copper, titanium nitride (TiN), metal silicide, polysilicon or the like. In some embodiments, the second electrode layer 22 includes nickel silicide or cobalt silicide. In some embodiments, the second electrode layer 22 and the first electrode layer 21 include a same material.

In some embodiments, the capacitor structure 20 is electrically connected to a first contact 51 and a second contact 52. In some embodiments, the first contact 51 and the second contact 52 are disposed over the upper portion 20c of the capacitor structure 20. The first contact 51 is electrically coupled to the first electrode layer 21. In some embodiments, the first contact 51 is disposed on the first electrode layer 21, and the first contact 51 extends through at least the oxide layer 41. In some embodiments, the first contact 51 is electrically isolated from the second electrode layer 22. In some embodiments, the first contact 51 is separated from the dielectric 23 and the second electrode layer 22.

In some embodiments, the second contact 52 is electrically coupled to the second electrode layer 22. In some embodiments, the second contact 52 is disposed adjacent to the first contact 51 and extends through the oxide layer 41. The second contact 52 is electrically isolated from the first contact 51. In some embodiments, the semiconductor device 40 is surrounded by a plurality of first contacts 51 and a plurality of second contacts 52. In some embodiments, the plurality of second contacts 52 are surrounded by the plurality of first contacts 51.

For ease of illustration, the first contact 51 and the second contact 52 are illustrated in simplified form. In some embodiments, the first contact 51 and the second contact 52 comprise a barrier layer, a seed layer, a metal fill layer, and/or other suitable layers. In some embodiments, the metal fill layer comprises tungsten, aluminum, copper, cobalt, and/or other suitable materials. In some embodiments, the first contact 51 and the second contact 52 comprise a metal silicide. Other structures and/or configurations of the first contact 51 and the second contact 52 are within the scope of the present disclosure.

In some embodiments, a semiconductor material layer 102 is disposed between the capacitor structure 20 and the semiconductor device 40. In some embodiments, the semiconductor material layer 102 separates the capacitor structure 20 from the semiconductor device 40 in the horizontal directions (i.e., the first direction X and a second direction Y shown in FIG. 3) and the vertical direction (i.e., a third direction Z shown in FIG. 3). In some embodiments, the semiconductor material layer 102 is disposed between the second isolation layer 33 and the semiconductor device 40. The capacitor structure 20 surrounds the semiconductor material layer 102 from the plan view, and the semiconductor material layer 102 surrounds at least a portion of the semiconductor device 40 from the plan view. In some embodiments, the semiconductor material layer 102 encircles the entire semiconductor device 40, as shown in FIG. 2.

In some embodiments, the semiconductor material layer 102 is on the second isolation layer 33, thereby being electrically isolated from the capacitor structure 20 by the second isolation layer 33. In some embodiments, sidewalls and a bottom of the semiconductor material layer 102 are conformal to the second isolation layer 33. In some embodiments, the semiconductor material layer 102 surrounds the semiconductor device 40. As shown in FIG. 2, the semiconductor material layer 102 has a rectangular shape from the plan view. It should be understood that such shape is not intended to be limiting, and the semiconductor material layer 102 may have other shapes in other embodiments. In some embodiments, the semiconductor material layer 102 includes a single crystalline semiconductor material such as, but not limited to, at least one of Si, Ge, SiGe, InGaAs, GaAs, InSb, GaP, GaSb, InAlAs, GaSbP, GaAsSb, or InP. In some embodiments, the semiconductor material layer 102 and the substrate 101 include a same semiconductor material. In some alternative embodiments, the semiconductor material layer 102 and the substrate 101 includes different semiconductor materials.

In some embodiments, a first isolation structure 35 may be disposed under the oxide layer 41 and may be formed adjacent to the sidewall portion 20b of the capacitor structure 20 to provide electrical isolation for the semiconductor device 40 from other elements or devices. The upper portion 20c is adjacent to the semiconductor device 40 in the first direction X, and the capacitor structure 20 and the semiconductor device 40 are separated by the first isolation structure 35. In some embodiments, the first isolation structure 35 is disposed between the semiconductor device 40 and the capacitor structure 20. The first isolation structure 35 and the capacitor structure 20 are separated in the first direction X by a first distance d. In one embodiment, the first distance d is greater than 5 μm. In some embodiments, the first isolation structure 35 is in contact with the semiconductor device 40 or the second isolation layer 33. In some embodiments, the first isolation structure 35 is a shallow trench isolation (STI). The first isolation structure 35 extends from the first surface 101a toward the second surface 101b of the substrate 101, and an upper surface of the first isolation structure 35 is coplanar with the first surface 101a. In some embodiments, a plurality of first isolation structures 35 are disposed between the sidewall portion 20b and the semiconductor device 40. In some embodiments, the first isolation structure 35 includes an isolation material. In some embodiments, the first isolation structure 35 includes oxide or nitride.

In some embodiments, a second isolation structure 37 is formed over the first electrode layer 21 to provide electrical isolation for the first contact 51. In some embodiments, the second isolation structure 37 surrounds at least a portion of the first contact 51. In some embodiments, the second isolation structure 37 is an STI. The second isolation structure 37 extends from the first surface 101a to the first electrode layer 21 of the capacitor structure 20. In some embodiments, the second isolation structure 37 is disposed under the oxide layer 41, and an upper surface of the second isolation structure 37 is coplanar with the first surface 101a. In some embodiments, a plurality of second isolation structures 37 surround the plurality of first isolation structures 35. In some embodiments, the second isolation structure 37 includes an isolation material. In some embodiments, the second isolation structure 37 includes oxide or nitride. In some embodiments, the first isolation structure 35 and the second isolation structure 37 include a same material.

The semiconductor device 40 is fabricated in and/or on the semiconductor material layer 102 in a region encircled by the sidewall portion 20b of the capacitor structure 20. The semiconductor device 40 is disposed over and separated from the capacitor structure 20. In some embodiments, the semiconductor device 40 is disposed over the second isolation layer 33. It should be noted that, in some embodiments, the semiconductor device 40 includes the first isolation structure 35 as shown in FIGS. 2 and 3; however, in other embodiments, the semiconductor device 40 may include components of a transistor, a photodetector, an insulated-gate bipolar transistor (IGBT), a MOS device, a FET such as a MOSFET, a capacitance device, various combinations thereof, and/or the like. The semiconductor device 40 in each of the semiconductor structures 100a, 100b, 100c, 100d, 100e and 100f can be same or different.

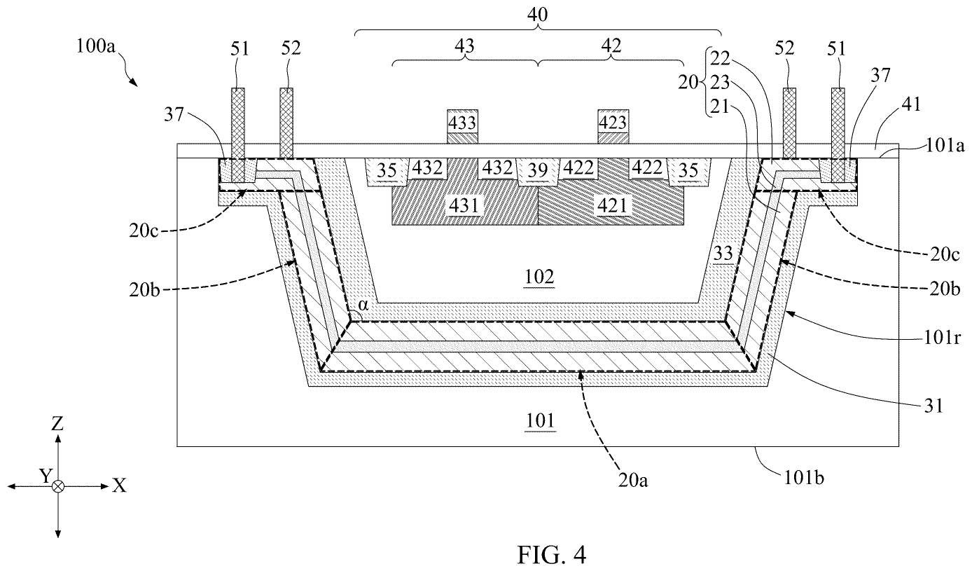

FIG. 4 is a schematic cross-sectional view of a semiconductor structure according to aspects of the present disclosure in some embodiments. Referring to FIG. 4, the semiconductor device 40 includes a complementary metal oxide semiconductor (CMOS) device. In some embodiments, the CMOS device includes a p-type MOS (PMOS) device 42 and an n-type MOS (NMOS) device 43. A bottom surface of the semiconductor device 40 may be at a vertical level lower than a vertical level of a bottom surface of the first isolation structure 35.

The PMOS device 42 includes an n-well region 421 under and between one of the first isolation structures 35 and an STI structure 39, p-type source/drain regions 422 in the n-well region 421, and a gate structure 423 over the n-well region 421. The NMOS device 43 is disposed adjacent to the PMOS device 42 and includes a p-well region 431 under and between one of the first isolation structures 35 and the STI structure 39, n-type source/drain regions 432 in the p-well region 431, and a gate structure 433 over the p-well region 431. In some embodiments, the oxide layer 41 serves as a gate dielectric layer between the gate structure 423 and the substrate 101, and a gate dielectric layer between the gat structure 433 and the substrate 101. Other structures and configurations of the semiconductor device 40, the PMOS device 42, and/or the NMOS device 43 are within the scope of the present disclosure. In some embodiments, the oxide layer 41 serves as a gate oxide of the semiconductor device 40. In some embodiments, the oxide layer 41 covers the semiconductor device 40, the first surface 101a, the second isolation layer 33, the semiconductor material layer 102, and the capacitor structure 20.

Additionally, an inter-layer dielectric (ILD) may be formed cover the semiconductor device 40 (i.e., the PMOS device 42 and the NMOS device 43), though not shown in FIGS. 3 and 4.

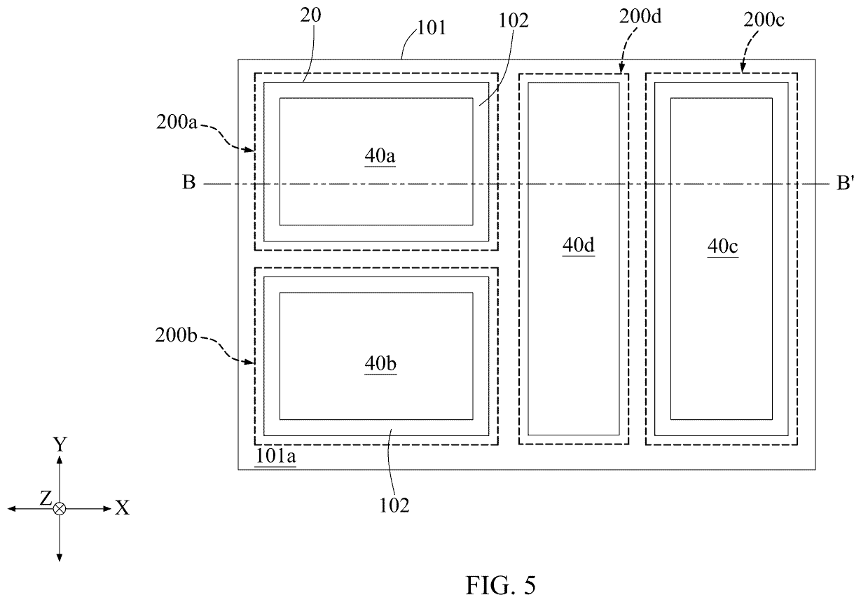

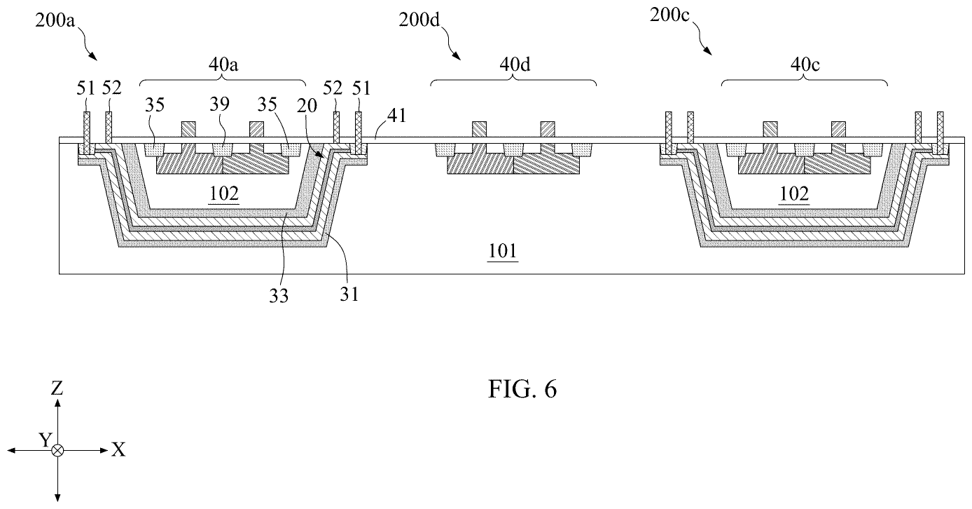

FIG. 5 is a schematic top view of a semiconductor structure according to aspects of the present disclosure in some embodiments. FIG. 6 is a schematic cross-sectional view taken along a line B-B′ in FIG. 5. Referring to FIGS. 5 and 6, semiconductor structures 200a, 200b, 200c and 200d are disposed on a first surface 101a of a substrate 101.

The semiconductor structures 200a, 200b and 200c illustrated in FIGS. 5 and 6 are similar to the semiconductor structures 100a, 100b and 100c illustrated in FIGS. 1, 2 and 3, except the semiconductor structure 200d shown in FIGS. 5 and 6 is free of the capacitor structure 20. A semiconductor device 40d of the semiconductor structure 200d is embedded in and surrounded by the substrate 101. Referring to FIGS. 5 and 6, a plurality of capacitor structures 20 are disposed on the first surface 101a of the substrate 101, and the semiconductor structures 200a, 200b, 200c and 200d include semiconductor devices 40a, 40b, 40c and 40d, respectively. The semiconductor devices 40a, 40b, 40c and 40d can be same or different.

In some embodiments, an oxide layer 41 is disposed over the semiconductor devices 40a, 40b, 40c and 40d. In some embodiments, the semiconductor structure 200a includes one of the capacitor structures 20, at least a portion of the corresponding capacitor structure 20 is disposed under the semiconductor device 40a, and another portion of the corresponding capacitor structure 20 is disposed adjacent to the semiconductor device 40a. In some embodiments, the semiconductor structure 200c includes one of the capacitor structures 20, at least a portion of the corresponding capacitor structure 20 is disposed under the semiconductor device 40c, and another portion of the corresponding capacitor structure 20 is disposed adjacent to the semiconductor device 40c. In some embodiments, the semiconductor structure 200d is disposed between the semiconductor structure 200a and the semiconductor structure 200b.

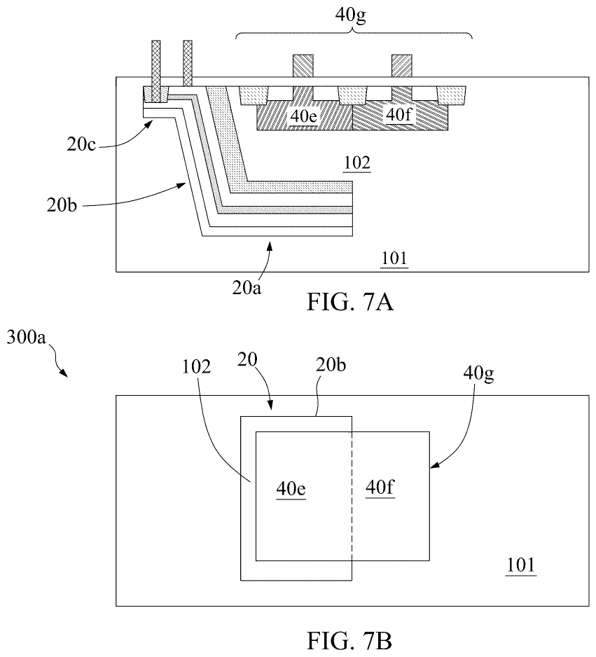

FIG. 7A is a schematic cross-sectional view of a semiconductor structure according to aspects of the present disclosure in some embodiments. FIG. 7B is a schematic top view of a semiconductor structure shown in FIG. 7A. In some embodiments, the semiconductor structure 300a illustrated in FIGS. 7A and 7B is similar to the semiconductor structure 100a illustrated in FIGS. 1, 2 and 3, except that only a first portion 40e of a semiconductor device 40g of the semiconductor structure 300a shown in FIGS. 7A and 7B overlaps a capacitor structure 20. In some embodiments, a second portion 40f of the semiconductor device 40g of the semiconductor structure 300a is offset from the capacitor structure 20. In some embodiments, a sidewall portion 20b of the capacitor structure 20 is disposed over a portion of a perimeter of a bottom portion 20a of the capacitor structure 20. In some embodiments, the first portion 40e of the semiconductor device 40g is in contact with a semiconductor material layer 102, and the second portion 40f of the semiconductor device 40g is in contact with a substrate 101. In some embodiments, the semiconductor structure 300a illustrated in FIGS. 7A and 7B is disposed adjacent to the semiconductor structure 100a illustrated in FIGS. 1, 2 and 3 and shares the same substrate 101.

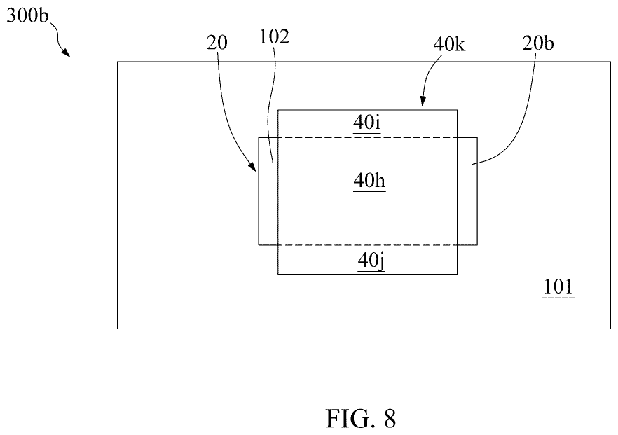

FIG. 8 is a schematic top view of a semiconductor structure according to aspects of the present disclosure in some embodiments. In some embodiments, the semiconductor structure 300b illustrated in FIG. 8 is similar to the semiconductor structure 100a illustrated in FIGS. 1, 2 and 3, except that only a third portion 40h of a semiconductor device 40k of the semiconductor structure 300b shown in FIG. 8 overlaps a capacitor structure 20. In some embodiments, a fourth portion 40i and a fifth portion 40j of the semiconductor device 40k of the semiconductor structure 300b are offset from the capacitor structure 20. In some embodiments, the third portion 40h is disposed between the fourth portion 40i and the fifth portion 40j. In some embodiments, a sidewall portion 20b of the capacitor structure 20 is segmented and discontinuous. In some embodiments, the third portion 40h of the semiconductor device 40k is in contact with a semiconductor material layer 102, and the fourth portion 40i and the fifth portion 40j of the semiconductor device 40k are in contact with a substrate 101. In some embodiments, the semiconductor structure 300b illustrated in FIG. 8 is disposed adjacent to the semiconductor structure 100a illustrated in FIGS. 1, 2 and 3 and shares the same substrate 101.

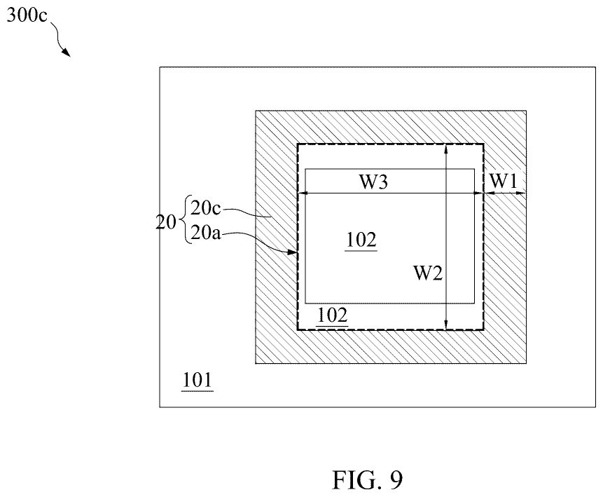

FIG. 9 is a schematic top view of a semiconductor structure according to aspects of the present disclosure in some embodiments. In some embodiments, a semiconductor structure 300c illustrated in FIG. 9 is similar to the semiconductor structure 100a illustrated in FIGS. 1, 2 and 3. In some embodiments, a width W1 of an upper portion 20c of a capacitor structure 20 is 0.3 μm, a first width W2 of a region surrounded by the upper portion 20c is 1 mm, a second width W3 of the region surrounded by the upper portion 20c is 1 mm, the first width W2 is perpendicular to the second width W3, and an area of the region surrounded by the upper portion 20c is 1 mm². In such embodiments, a suitable metal-insulator-metal (MIM) capacitor structure has a capacitance density of about 1.5 μF/mm²; if the suitable MIM capacitor structure has a surface area of 1 mm², the MIM capacitor may have a capacitance of about 1.5 μF. In some embodiments, a semiconductor material layer 102 and a semiconductor device 40 are disposed within the region, and a capacitance of the capacitor structure 20 is 1.2*10⁻³/mm² (=1 mm*0.3 μm*4). As such, a capacitance density of the capacitor structure 20 is 1.25 mF/mm² (=1.5 μF/1.2*10⁻³/mm²), and thus the capacitance density of the capacitor structure 20 is about 500 times that of the suitable MIM capacitor structure.

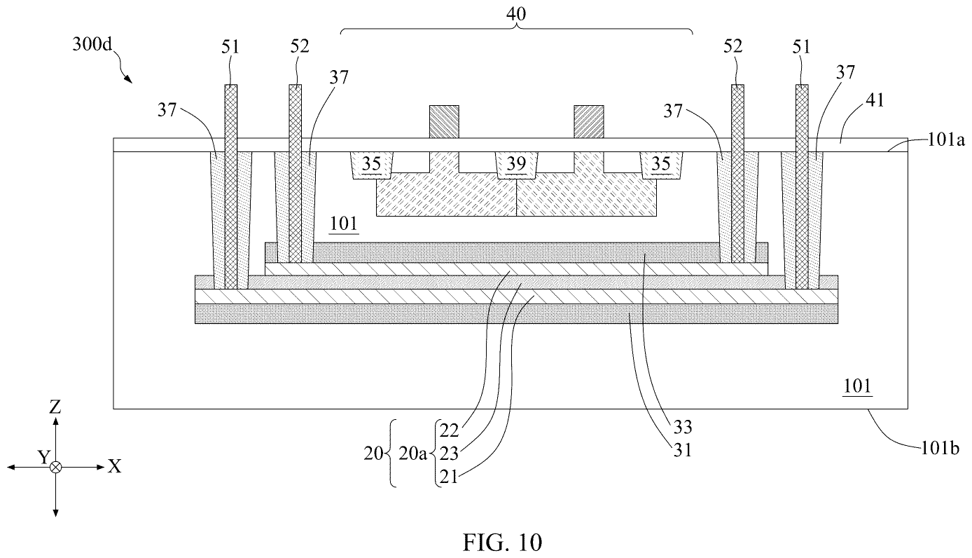

FIG. 10 is a schematic cross-sectional view of a semiconductor structure according to aspects of the present disclosure in some embodiments. In some embodiments, the semiconductor structure 300d illustrated in FIG. 10 is similar to the semiconductor structure 100a illustrated in FIGS. 1, 2 and 3, except that a capacitor structure 20 of the semiconductor structure 300d is disposed within a substrate 101 and includes only a bottom portion 20a. In some embodiments, a sidewall portion 20b and an upper portion 20c of the capacitor structure 20 are omitted. In some embodiments, the capacitor structure 20 extends only along the first direction X.

In some embodiments, the capacitor structure 20 includes a first electrode layer 21, a dielectric 23 over the first electrode layer 21, and a second electrode layer 22 over the dielectric 23. In some embodiments, an area of a dielectric 23 is substantially equal to an area of a first electrode layer 21. In some embodiments, a portion of the dielectric 23 is exposed through the second electrode layer 22. In some embodiments, a first contact 51 and a second contact 52 are disposed over and electrically coupled to the bottom portion 20a of the capacitor structure 20. Each of the first contact 51 and the second contact 52 is at least partially surrounded by a plurality of second isolation structures 37. The first contact 51 is disposed on and electrically coupled to a first electrode layer 21, and the first contact 51 extends through the dielectric 23, a semiconductor material layer 102 and an oxide layer 41. In some embodiments, the first contact 51 surrounded by the second isolation structure 37 is electrically isolated from the second electrode layer 22.

The second contact 52 is disposed on and electrically coupled to the second electrode layer 22. In some embodiments, a second isolation layer 33 covers the entire second electrode layer 22, and the second contact 52 extends through a semiconductor material layer 102, the second isolation layer 33 and the oxide layer 41. In some embodiments, the semiconductor structure 300d illustrated in FIG. 10 is disposed adjacent to the semiconductor structure 100a illustrated in FIGS. 1, 2 and 3 and shares the same substrate 101.

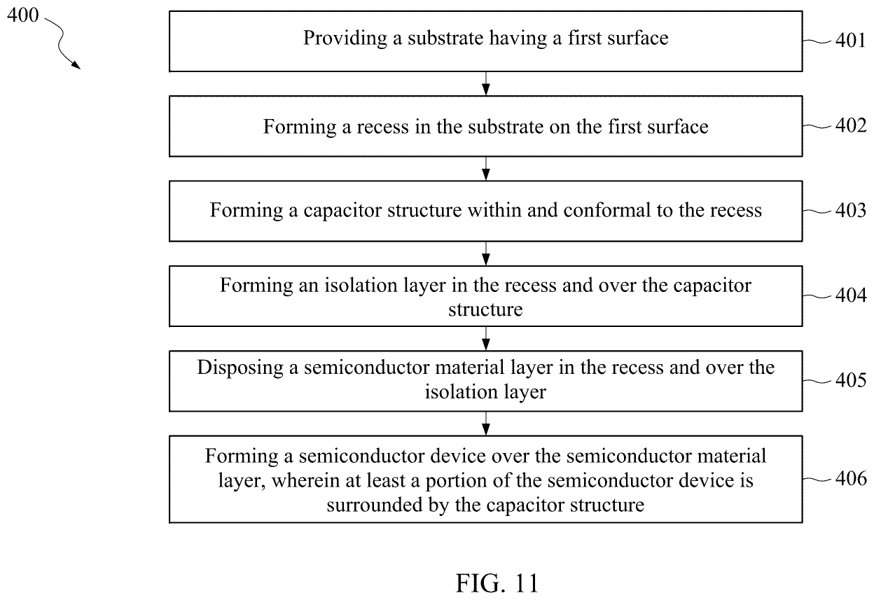

In accordance with some embodiments of the present disclosure, a method for manufacturing a semiconductor structure is disclosed. In some embodiments, the semiconductor structure 100a is fabricated by the method 400. FIG. 11 is a flowchart of the method 400 in accordance with some embodiments. The method 400 includes a number of operations (401 to 406), and descriptions and illustrations are not deemed as a limitation to a sequence of the operations. Additional steps can be provided before, during, and after the operations shown in FIG. 11, and some of the operations described below can be replaced or eliminated in other embodiments of the method 400. An order of the operations may be interchangeable.

Operation 401 includes providing a substrate having a first surface. Operation 402 includes forming a recess in the first surface of the substrate. Operation 403 includes forming a capacitor structure within and conformal to the recess. Operation 404 includes forming an isolation layer in the recess and over the capacitor structure. Operation 405 includes disposing a semiconductor material layer in the recess and over the isolation layer. Operation 406 includes forming a semiconductor device over the semiconductor material layer, wherein at least a portion of the semiconductor device is surrounded by the capacitor structure.

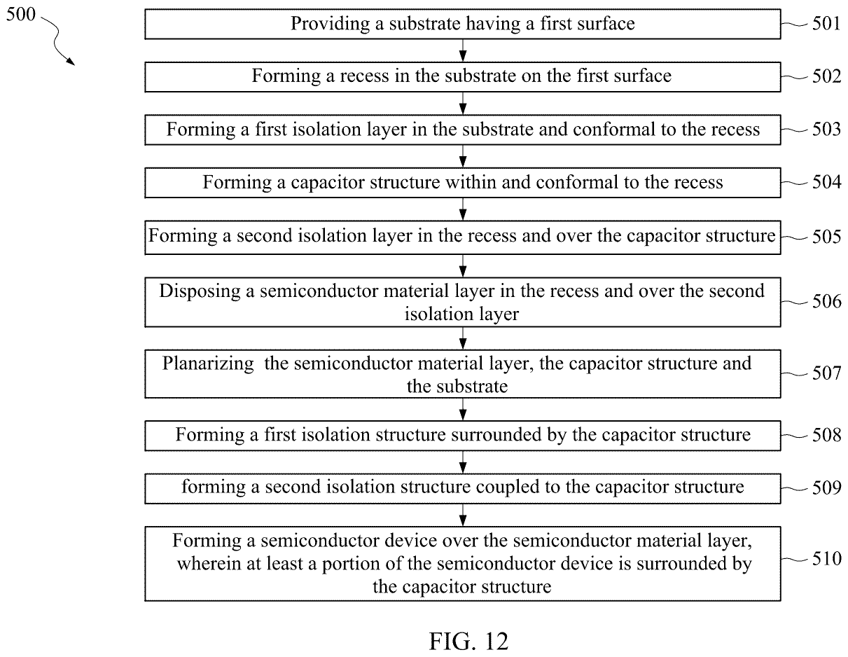

In accordance with some embodiments of the present disclosure, a method for manufacturing a semiconductor structure is disclosed. In some embodiments, the semiconductor structure 100a is fabricated by the method 500. FIG. 12 is a flowchart of the method 500 in accordance with some embodiments. The method 500 includes a number of operations (501 to 510), and descriptions and illustrations are not deemed as a limitation to a sequence of the operations. Additional steps can be provided before, during, and after the operations shown in FIG. 12, and some of the operations described below can be replaced or eliminated in other embodiments of the method 500. An order of the operations may be interchangeable.

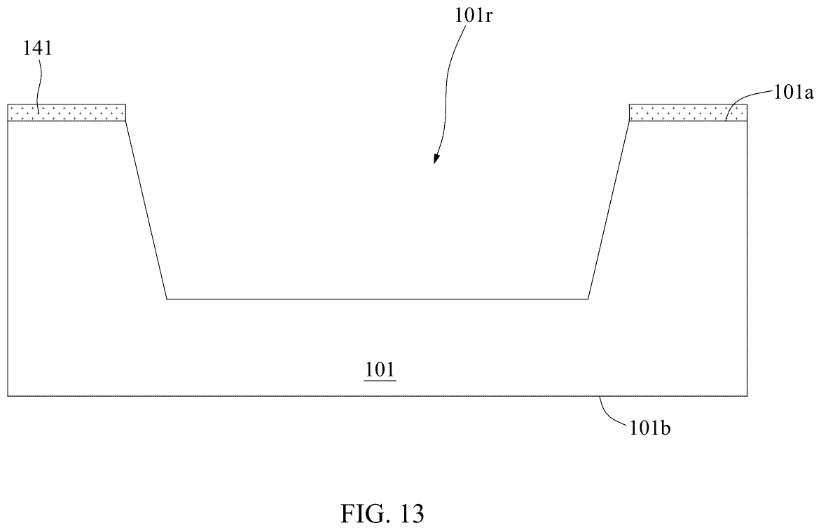

FIGS. 13 to 31 are schematic cross-sectional views of one or more operations of the method 500 for manufacturing a semiconductor structure in accordance with some embodiments of the present disclosure. The method 500 begins with operation 501. Operation 501 includes providing or receiving a substrate 101 having a first surface 101a and a second surface 101b opposite to the first surface 101a. The method 500 continues with operation 502. Operation 502 includes forming a recess 101r in the first surface 101a of the substrate 101. In some embodiments, operation 501 and operation 502 of the method 500 are similar to operation 401 and operation 402 of the method 400.

Referring to FIG. 13, in accordance with some embodiments, a mask layer 141 is formed over the first surface 101a of the substrate 101, and the recess 101r is formed in the substrate 101 using the mask layer 141 as a removal template. In some embodiments, the recess 101r is U-shaped.

In some embodiments, the mask layer 141 is a hard mask layer. The hard mask layer is formed by at least one of physical vapor deposition (PVD) (e.g., sputtering and/or evaporation), chemical vapor deposition (CVD) (e.g., low pressure CVD (LPCVD), ultrahigh vacuum CVD (UHVCVD), reduced pressure CVD (RPCVD), plasma-enhanced CVD (PECVD), and/or atmospheric pressure CVD (APCVD)), spin coating, growth, or other suitable techniques. In some embodiments, the hard mask layer comprises at least one of silicon and oxygen, silicon and nitrogen, nitrogen, silicon (e.g., polycrystalline silicon), or other suitable materials.

In some embodiments, the recess 101r is formed in the substrate 101 by performing an etching process to remove portions of the substrate 101 exposed by the mask layer 141. The substrate 101 is etched from the first surface 101a to the second surface 101b to form the recess 101r. The etching process comprises at least one of a plasma etching process, a reactive ion etching (RIE) process, or other suitable techniques. Other structures and configurations of the recess 101r are within the scope of the present disclosure.

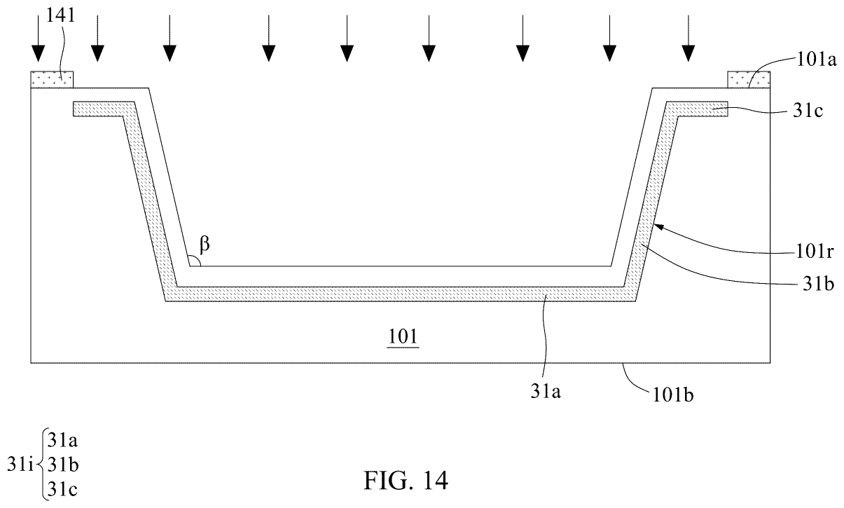

The method 500 continues with operation 503. Operation 503 includes forming a first implanted region 31i in the substrate 101 and conformal to the recess 101r. In some embodiments, referring to FIG. 14, a bottom and a sidewall of the recess 101r are treated with an ion implant to form a dielectric material. In some embodiments, an implantation process is performed to implant oxygen, nitrogen, carbon, or similar ions into the substrate 101 along the bottom and the sidewall of the recess 101r, forming the first implanted region 31i. The first implanted region 31i includes a bottom portion 31a, a sidewall portion 31b and an upper portion extending from the sidewall portion 31b and away from the bottom portion 31a. In some embodiments, an angle β between the bottom portion 31a and the sidewall portion 31b is greater than 90°.

In some embodiments, the first implanted region 31i includes oxygen ions. A depth of the first implanted region 31i is determined by a level of energy used to perform the implantation process. For example, in an embodiment, oxygen ions are implanted at a dose of about 5e14 to about 5e18 atoms/cm² and at an energy of about 100 KeV to about 500 KeV.

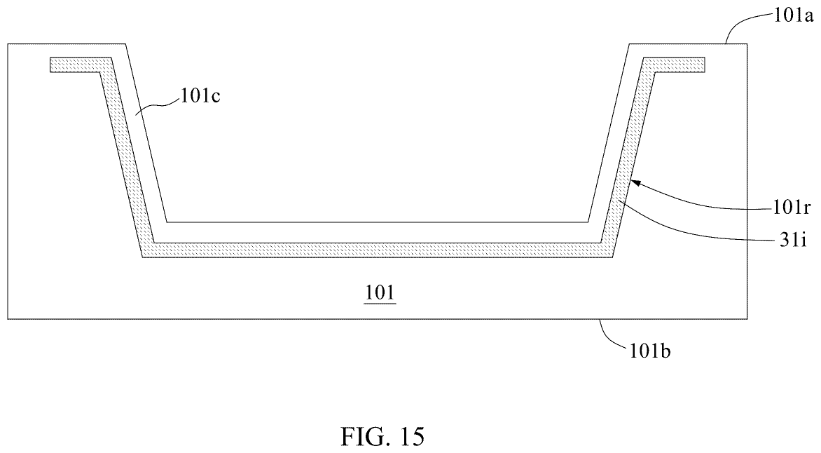

In some embodiments, referring to FIG. 15, the mask layer 141 is removed. The mask layer 141 is stripped or washed away after the first implanted region 31i is formed. In some embodiments, an epitaxial growth process is performed to form an epitaxy (or epi) semiconductor layer 101c after the implantation process. In some embodiments, the epitaxy semiconductor layer 101c includes silicon. In some embodiments, the epitaxy semiconductor layer 101c is formed on the bottom and the sidewall of the recess 101r and over the first surface 101a. In some embodiments, the epitaxy semiconductor layer 101c includes a material same as a material of the substrate 101 and redefines the first surface 101a of the substrate 101.

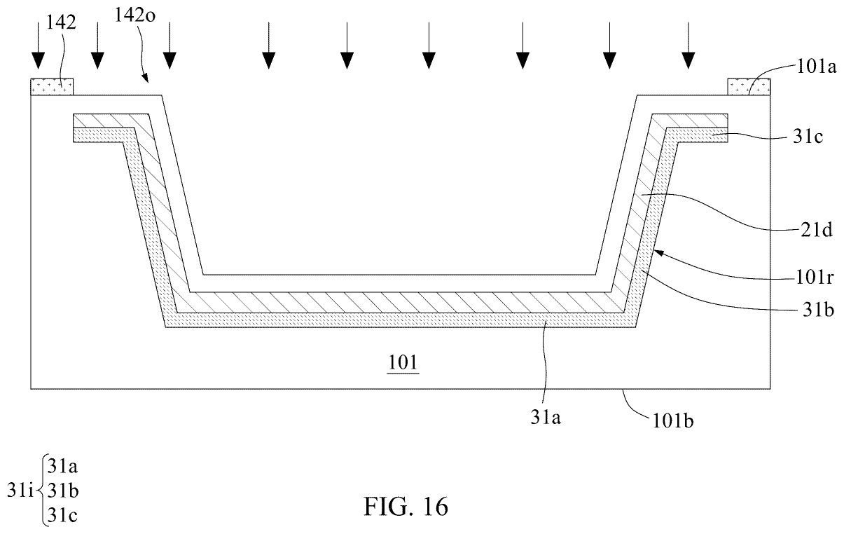

The method 500 continues with operation 504. Operation 504 includes forming a capacitor structure 20 within and conformal to the recess 101r. In some embodiments, operation 504 of the method 500 is similar to operation 403 of the method 400. In some embodiments, referring to FIG. 16, a mask layer 142 having an opening 142o is formed over the first surface 101a. In some embodiments, operation 504 includes forming a first doped layer 21d in the recess 101r. In some embodiments, the first doped layer 21d is conformal to the first implanted region 31i and is formed over the bottom portion 31a, the sidewall portion 31b and the upper portion 31c of the first implanted region 31i. The first doped layer 21d covers an entirety of the first implanted region 31i.

In some embodiments, the first doped layer 21d is formed by introducing an impurity into the epitaxy semiconductor layer 101c and/or the substrate 101. The impurity may be a p-type dopant, such as at least one of boron, BF₂, aluminum, gallium, indium, or other suitable p-type dopants. The impurity may be an n-type dopant, such as at least one of phosphorous, arsenic, or other suitable n-type dopants. In some embodiments, the first doped layer 21d includes nickel ion. A depth of the first doped layer 21d is determined by a level of energy used to introduce the impurity. For example, in an embodiment, nickel ions are implanted at a dose of about 10¹³ to about 10¹⁵ atoms/cm² and at an energy of about 200 KeV to about 600 KeV.

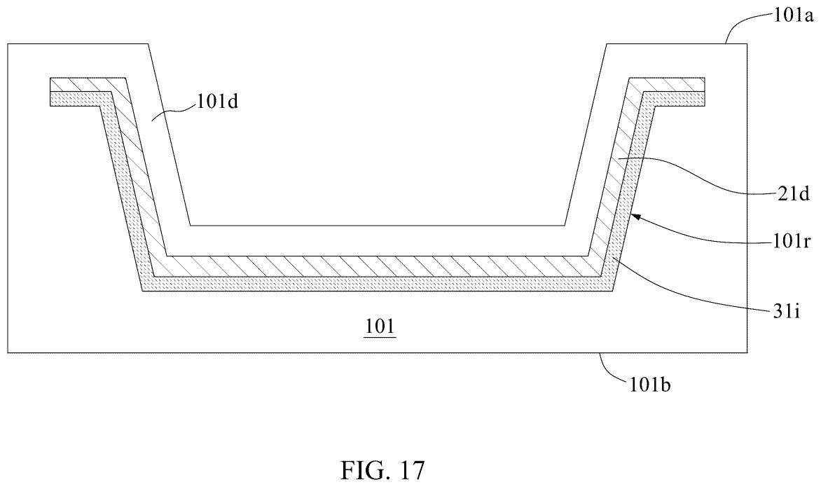

In some embodiments, referring to FIG. 17, the mask layer 142 is removed. The mask layer 142 is stripped or washed away after the first doped layer 21d is formed. In some embodiments, an epitaxial growth process is performed to form an epitaxy (or epi) semiconductor layer 101d over the first doped layer 21d. In some embodiments, the epitaxy semiconductor layer 101d is formed over the first surface 101a and the entire first doped layer 21d. In some embodiments, the epitaxy semiconductor layer 101d includes silicon. In some embodiments, the epitaxy semiconductor layer 101d includes a material same as a material of the substrate 101 and redefines the first surface 101a of the substrate 101.

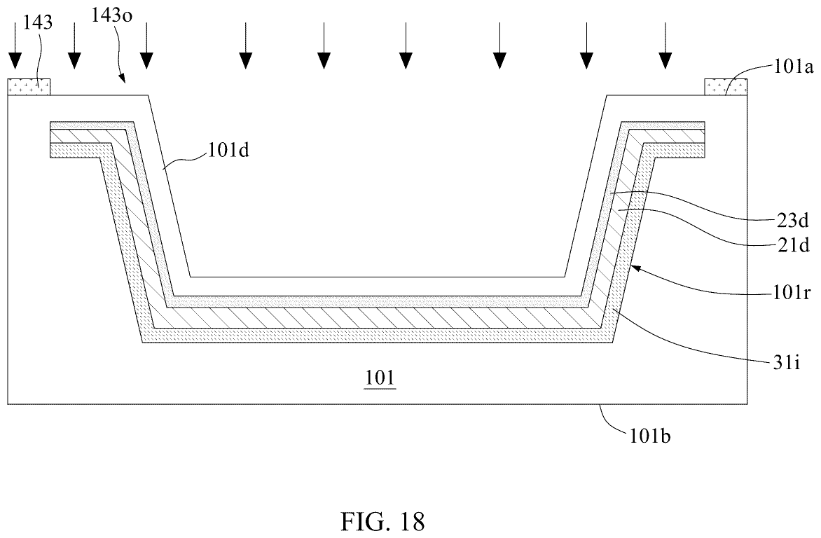

In some embodiments, referring to FIG. 18, operation 504 further includes forming a second doped layer 23d in the recess 101r. In some embodiments, the second doped layer 23d is conformal to and formed over the first doped layer 21d. The second doped layer 23d covers an entirety of the first doped layer 21d. In some embodiments, the mask layer 143 is disposed over the first surface 101a of the substrate 101 during the formation of the second doped layer 23d.

In some embodiments, an implantation process is performed to implant oxygen, nitrogen, carbon, or similar ions into the epitaxy semiconductor layer 101d and/or the substrate 101 along the bottom and the sidewall of the recess 101r, thus forming the second doped layer 23d. In some embodiments, the epitaxy semiconductor layer 101d and/or the substrate 101 is implanted with oxygen ions or nitrogen ions at a dose of about 10¹⁴ to about 10¹⁸ atoms/cm² and at an energy of about 100 KeV to about 500 KeV.

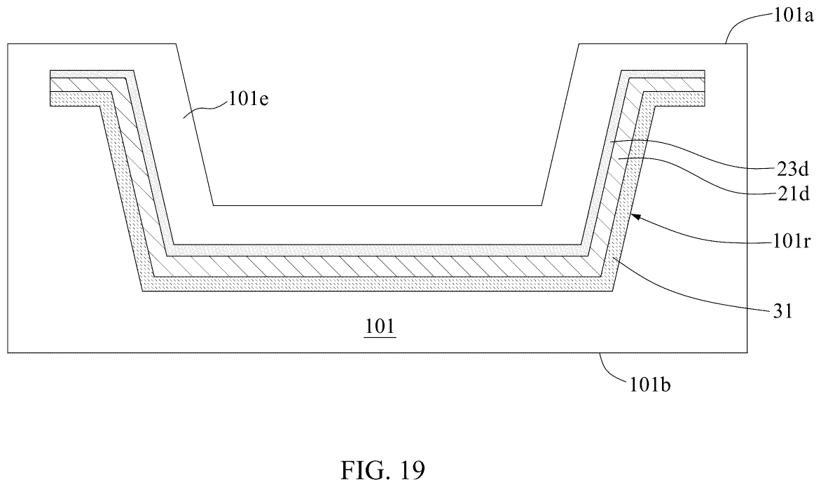

In some embodiments, referring to FIG. 19, the mask layer 143 is removed. The mask layer 143 is stripped or washed away after the second doped layer 23d is formed. In some embodiments, an epitaxial growth process is performed to form an epitaxy (or epi) semiconductor layer 101e over the second doped layer 23d. In some embodiments, the epitaxy semiconductor layer 101e is formed over the first surface 101a and an entirety of the second doped layer 23d. In some embodiments, the epitaxy semiconductor layer 101e includes silicon. In some embodiments, the epitaxy semiconductor layer 101e includes a material same as a material of the substrate 101 and redefines the first surface 101a of the substrate 101.

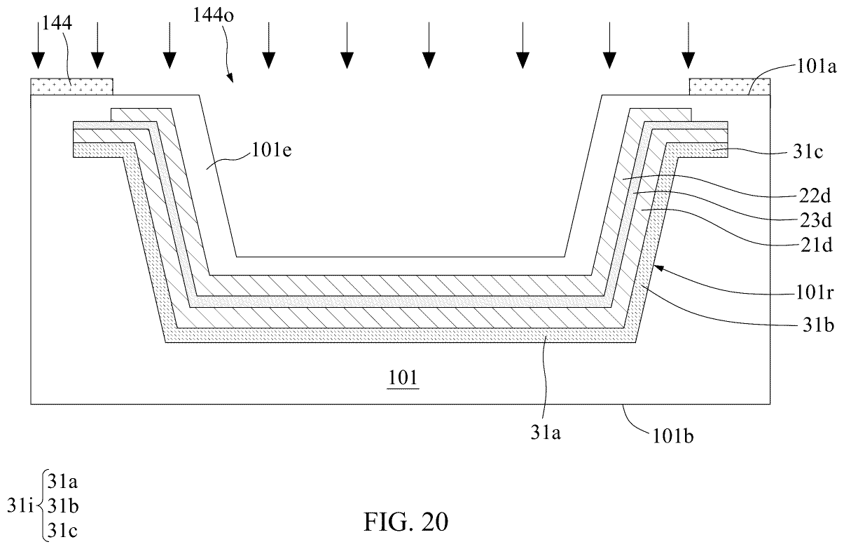

In some embodiments, operation 504 further includes forming a third doped layer 22d in the recess 101r. In some embodiments, referring to FIG. 20, a mask layer 144 having an opening 144o is formed over the first surface 101a. In some embodiments, the opening 144o is smaller than the opening 142o of the mask 142.

In some embodiments, the third doped layer 22d is formed over and conformal to the second doped layer 23d. The third doped layer 22d is formed over the bottom portion 31a, the sidewall portion 31b and a portion of the upper portion 31c of the first implanted region 31i. The third doped layer 22d covers a central portion of the second doped layer 23d, and a peripheral portion of the second doped layer 23d is exposed through the third doped layer 22d. In some embodiments, the third doped layer 22d covers the entire second doped layer 23d. The first doped layer 21d, the second doped layer 23d and the third doped layer 22d will form the capacitor structure 20 in subsequent steps.

In some embodiments, the third doped layer 22d is formed by introduction of an impurity into the epitaxy semiconductor layer 101e and/or the substrate 101. The impurity may be a p-type dopant, such as at least one of boron, BF₂, aluminum, gallium, indium, and other suitable p-type dopants. The impurity may be an n-type dopant, such as at least one of phosphorous, arsenic, and other suitable n-type dopants. In some embodiments, the third doped layer 22d includes nickel ion. A depth of the third doped layer 22d is determined by a level of energy used to introduce the impurity. For example, in an embodiment, nickel ions are implanted at a dose of about 10¹³ to about 10¹⁵ atoms/cm² and at an energy of about 200 KeV to about 600 KeV.

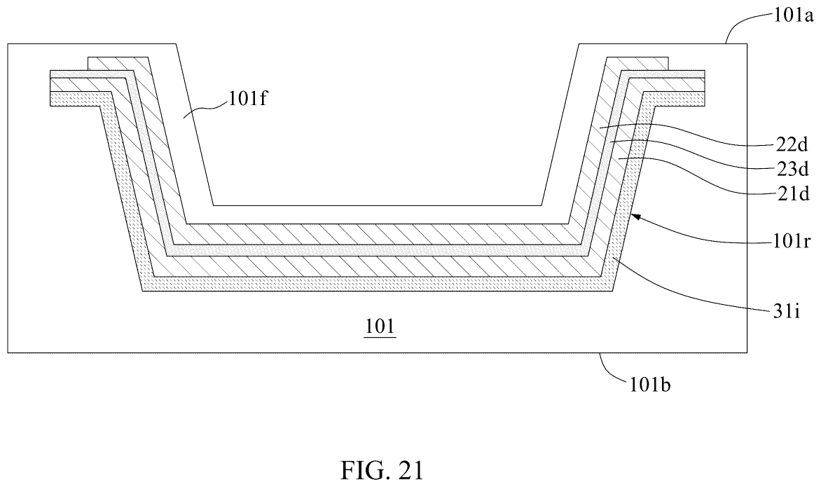

In some embodiments, referring to FIG. 21, the mask layer 144 is removed. The mask layer 144 is stripped or washed away after the third doped layer 22d is formed. In some embodiments, an epitaxial growth process is performed to form an epitaxy (or epi) semiconductor layer 101f over the third doped layer 22d. In some embodiments, the epitaxy semiconductor layer 101f is formed over the first surface 101a and an entirety of the third doped layer 22d. In some embodiments, the epitaxy semiconductor layer 101f includes silicon. In some embodiments, the epitaxy semiconductor layer 101f includes a material same as a material of the substrate 101 and redefines the first surface 101a of the substrate 101.

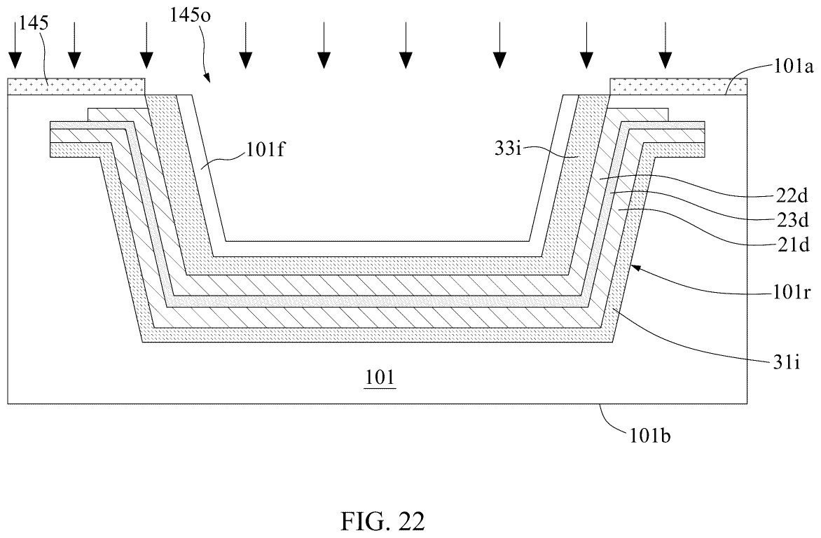

The method 500 continues with operation 505. Operation 505 includes forming a second implanted region 33i in the recess 101r and over the capacitor structure 20. In some embodiments, operation 505 of the method 500 is similar to operation 404 of the method 400. In some embodiments, referring to FIG. 22, a mask layer 145 having an opening 145o is formed over the first surface 101a, and the epitaxy semiconductor layer 101f is treated with an ion implant through the opening 145o to form a dielectric material. In some embodiments, an implantation process is performed to implant oxygen, nitrogen, carbon, or similar ions into the substrate 101 and the epitaxy semiconductor layer 101f, forming the second implanted region 33i. The second implanted region 33i is conformal to the third doped layer 22d.

In some embodiments, the second implanted region 33i includes oxygen ions. A depth of the second implanted region 33i is determined by a level of energy used to perform the implantation process. For example, in an embodiment, oxygen ions are implanted at a dose of about 10¹⁴ to about 10¹⁸ atoms/cm² and at an energy of about 100 KeV to about 500 KeV.

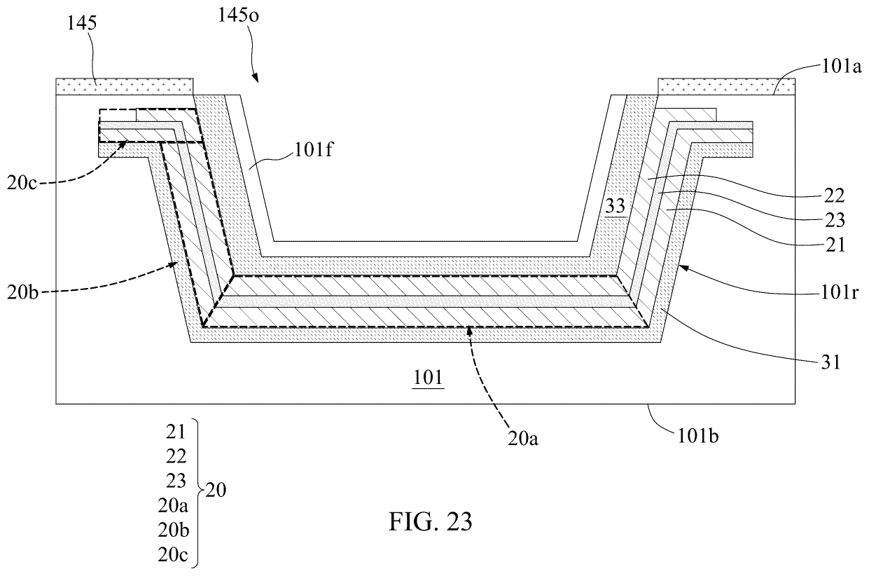

In some embodiments, referring to FIG. 23, operation 504 further includes annealing the substrate 101 to transfer the first implanted region 31i to a first isolation layer 31, the second implanted region 33i to a second isolation layer 33, the first doped layer 21d to a first electrode layer 21, the second doped layer 23d to a dielectric 23, and the third doped layer 22d to a second electrode layer 22, thus forming the capacitor structure 20 between the first isolation layer 31 and the second isolation layer 33. In some embodiments, the first electrode layer 21 and the second electrode layer 22 include nickel salicide. In some embodiments, the first isolation layer 31 and the second isolation layer 33 includes silicon dioxide. In some embodiments, two ends of the second isolation layer 33 are made coplanar with the first surface 101a of the substrate 101. In some embodiments, the annealing is performed after the second implanted region 33 is formed.

In some embodiments, the formation of the capacitor structure 20 includes forming a bottom portion 20a within the recess 101r, forming a sidewall portion 20b disposed over and coupled to the bottom portion 20a within the recess 101r, and forming an upper portion 20c coupled to and extending from the sidewall portion 20b and away from the bottom portion 20a. In some embodiments, the bottom portion 20a, the sidewall portion 20b and the upper portion 20c are formed simultaneously. In some embodiments, an angle α formed between the bottom portion 20a and sidewall portion 20b is greater than 90°. In some embodiments, the angle α is substantially identical to the angle β.

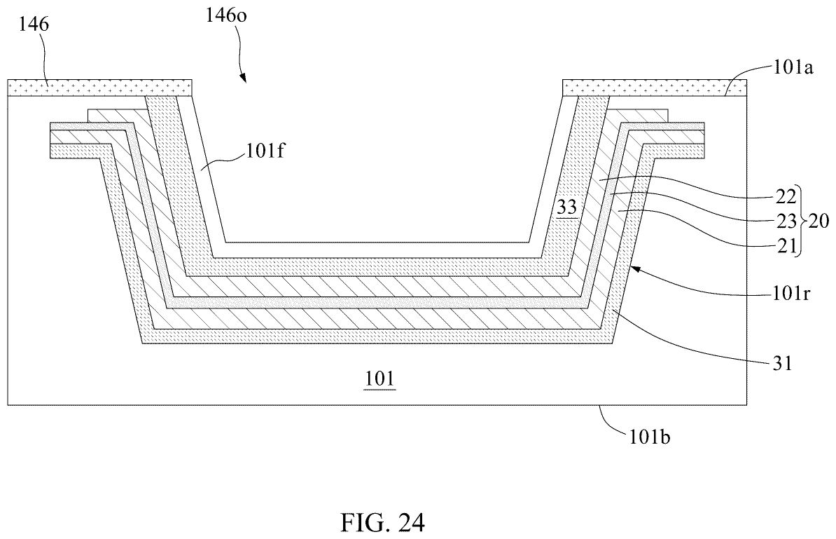

In some embodiments, referring to FIG. 24, the mask layer 145 is removed, and a mask layer 146 is disposed on the first surface 101a of the substrate 101. The mask layer 145 is stripped or washed away after the capacitor structure 20 is formed. In some embodiments, the mask layer 146 covers the first surface 101a and the two ends of the second isolation layer 33, and includes an opening 146o exposing the recess 101r and the epitaxy semiconductor layer 101f.

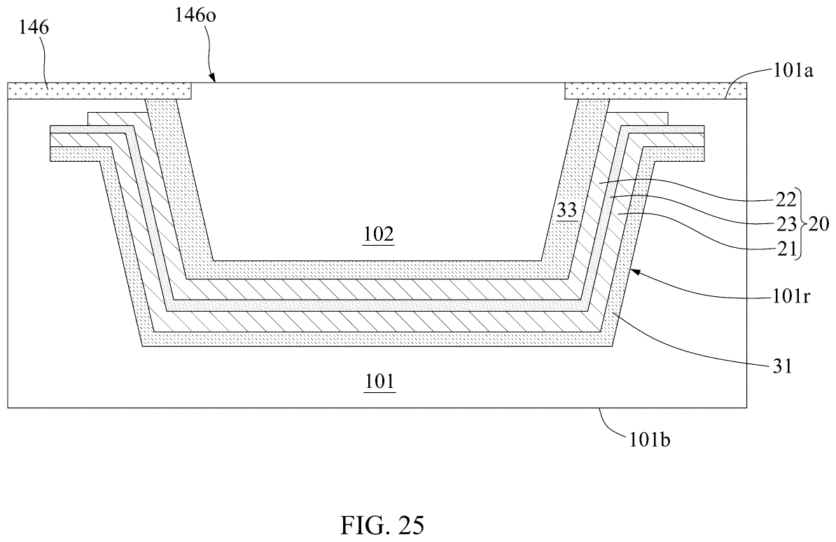

The method 500 continues with operation 506. Operation 506 includes forming a semiconductor material layer 102 in the recess 101r and over the second isolation layer 33. In some embodiments, operation 506 of the method 500 is similar to operation 405 of the method 400. In some embodiments, referring to FIG. 25, the semiconductor material layer 102 is formed in the recess 101r through the opening 146o. In some embodiments, the opening 146o and the recess 101r have the semiconductor material layer 102 formed therein, and the semiconductor material layer 102 is conformal to the recess 101r. In some embodiments, the semiconductor material layer 102 is formed over the first surface 101a of the substrate 101 and in the recess 101r. The semiconductor material layer 102 may be deposited by PVD, CVD, sputter deposition, or another technique for depositing the selected material.

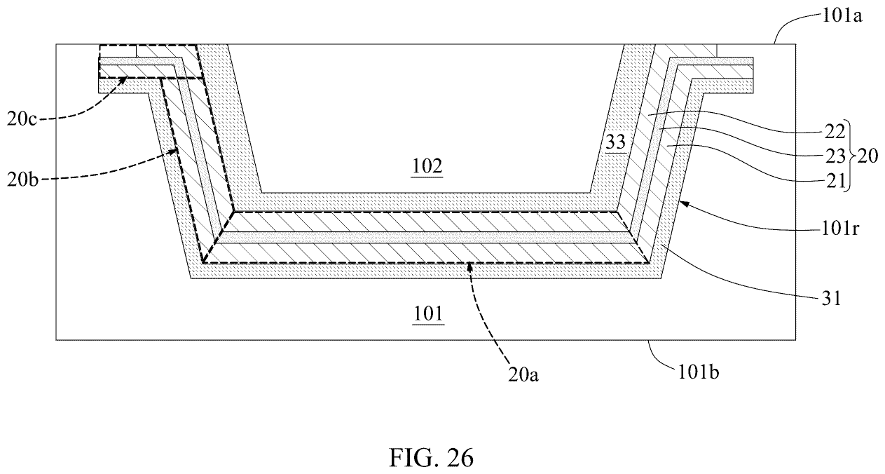

The method 500 continues with operation 507. Operation 507 includes planarizing the semiconductor material layer 102, the capacitor structure 20 and the substrate 101. In some embodiments, referring to FIG. 26, the semiconductor material layer 102 may be deposited over the surface 101a of the substrate 101 and then planarized, such as by a CMP processes or a mechanical grinding process. A planarization process is performed to co-planarize top surfaces of the semiconductor material layer 102, the substrate 101, the upper portion 20c of the capacitor structure 20, and the second isolation layer 33. In some embodiments, after the planarization process, the second electrode layer 22 of the upper portion 20c and the two ends of the second isolation layer 33 are exposed.

The method 500 continues with operations 508 and 509. Operation 508 includes forming a first isolation structure 35 surrounded by the capacitor structure 20. Operation 509 includes forming a second isolation structure 37 coupled to the capacitor structure 20. In some embodiments, operation 508 further includes forming a third isolation structure 39 surrounded by the capacitor structure 20 and disposed adjacent to the first isolation structure 35.

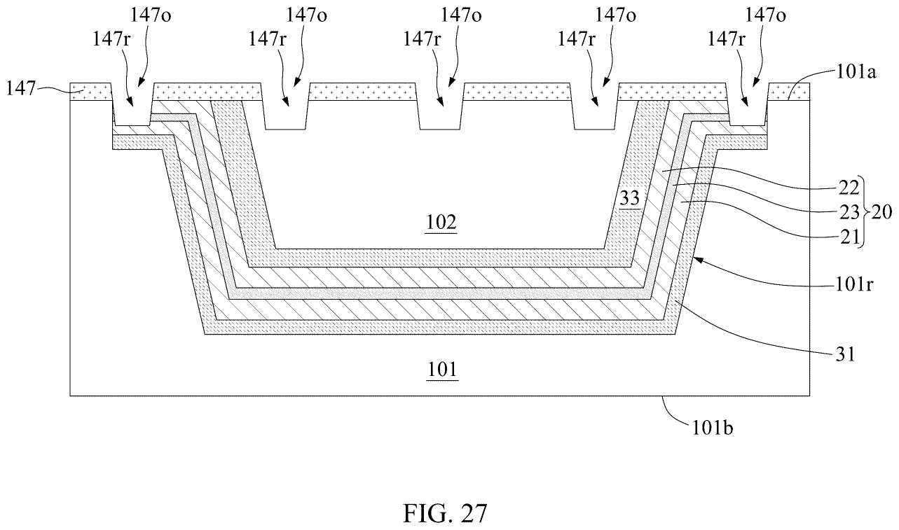

Referring to FIG. 27, in accordance with some embodiments, a mask layer 147 having a plurality of openings 147o is formed over the first surface 101a, the capacitor structure 20 and the semiconductor material layer 102, and recesses 147r are formed using the mask layer 147 as a removal template. In some embodiments, some of the recesses 147r expose the first electrode layer 21, and some of the recesses 147r are formed over the capacitor structure 20. In some embodiments, a portion of the semiconductor material layer 102 is removed, the second isolation layer 33 is exposed through some of the recesses 147r.

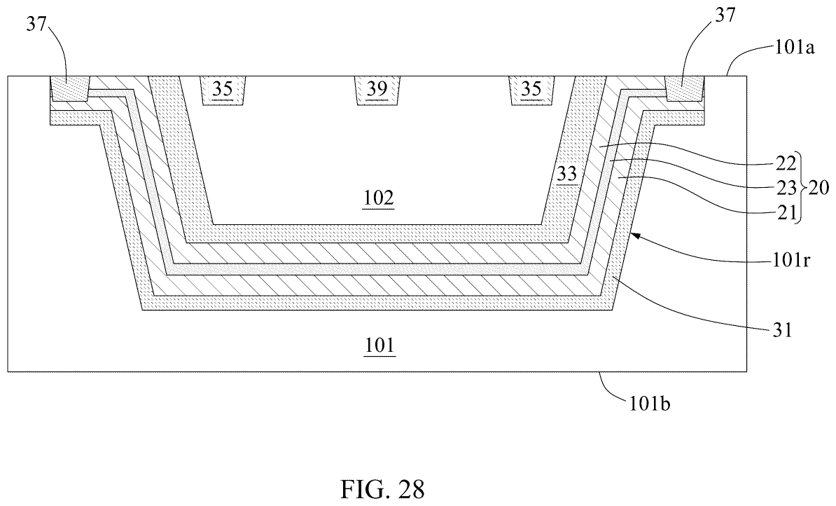

Referring to FIG. 28, a plurality of first isolation structures 35 are formed adjacent to the sidewall portion 20b, a plurality of second isolation structures 37 are formed over the first electrode layer 21, and a third isolation structure 39 is formed between the first isolation structures 35. The first isolation structures 35 are surrounded by the capacitor structure 20. The plurality of second isolation structures 37 are coupled to the first electrode layer 21 and extend through the dielectric 23 and the second electrode layer 22. In some embodiments, an isolation material is disposed in the recesses 147r, and the first isolation structures 35, the second isolation structures 37 and the third isolation structure 39 are formed simultaneously. In some embodiments, a planarization process, such as a CMP process or a mechanical grinding process, is performed to planarize top surfaces of the semiconductor material layer 102, the substrate 101, the upper portion 20c of the capacitor structure 20, the second isolation layer 33, the first isolation structures 35, the second isolation structures 37 and the third isolation structure 39.

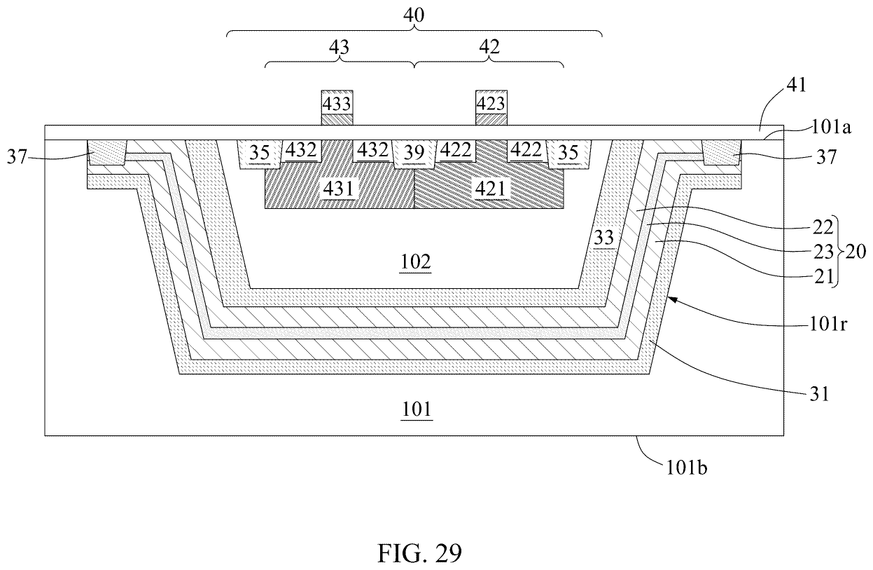

The method 500 continues with operation 510. Operation 510 includes forming a semiconductor device 40 over the semiconductor material layer 102, wherein at least a portion of the semiconductor device 40 is surrounded by the capacitor structure 20. In some embodiments, operation 510 of the method 500 is similar to operation 406 of the method 400. Referring to FIG. 29, the semiconductor device 40 is formed over the capacitor structure 20, and at least a portion of the semiconductor device 40 is surrounded by the semiconductor material layer 102. In some embodiments, the formation of the semiconductor device 40 includes disposing an oxide layer 41 over the capacitor structure 20, the second isolation layer 33, the semiconductor material layer 102 and the first surface 101a of the substrate 101. In some embodiments, the second isolation layer 33 is enclosed by the oxide layer 41 and the capacitor structure 20. The oxide layer 41 may be deposited by PVD, CVD, sputter deposition, or another technique for depositing the selected material.

In some embodiments, the semiconductor device 40 includes a CMOS device, and a PMOS device 42 and an NMOS device 43 are formed. In some embodiments, the formation of the semiconductor device 40 includes forming an n-well region 421 under and between one of the first isolation structures 35 and the third isolation structure 39, forming p-type source/drain regions 422 in the n-well region 421, and forming a gate structure 423 over the n-well region 421. In some embodiments, the formation of the semiconductor device 40 includes forming a p-well region 431 under and between one of the first isolation structure 35 and the third isolation structure 39, forming n-type source/drain regions 432 in the p-well region 431, and forming a gate structure 433 over the p-well region 431.

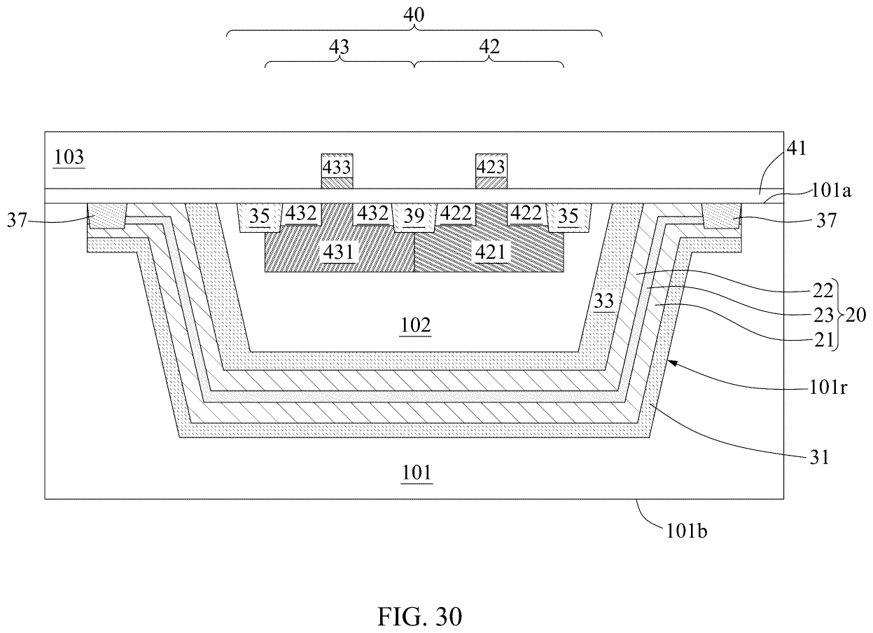

In some embodiments, the method 500 further includes disposing an interlayer dielectric 103 over the oxide layer 41. In some embodiments, referring to FIG. 30, the interlayer dielectric 103 is disposed over the semiconductor device 40 and the capacitor structure 20. The interlayer dielectric 103 is disposed over the first surface 101a of the substrate 101. In some embodiments, the interlayer dielectric 103 is disposed by deposition, CVD or any other suitable operation.

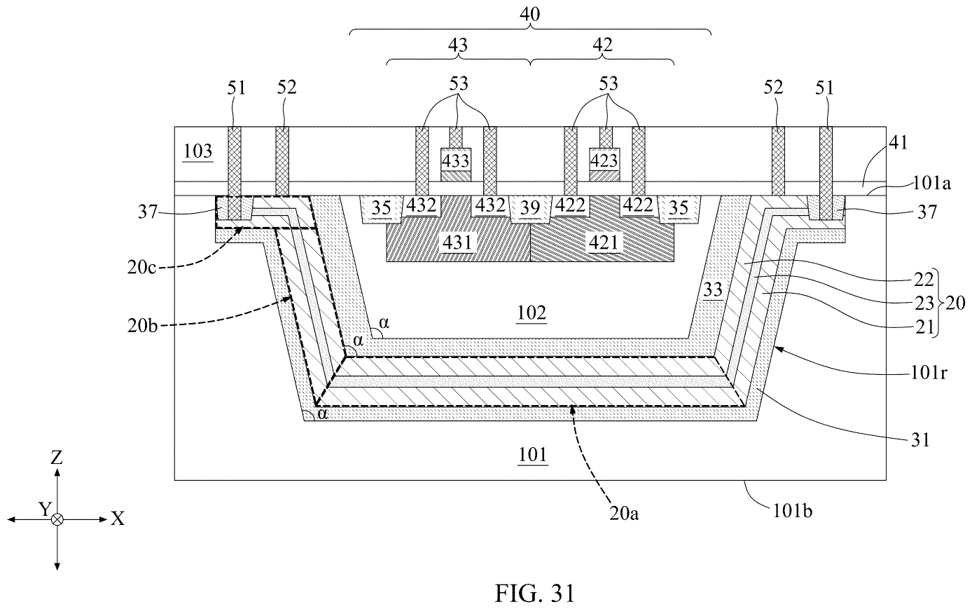

In some embodiments, the method 500 further includes removing portions of the interlayer dielectric 103, and forming several contacts within resulting openings. In some embodiments, referring to FIG. 31, a first contact 51 is formed over and electrically coupled to the first electrode layer 21, wherein a portion of the first contact 51 is surrounded by the second isolation structure 37. In some embodiments, a second contact 52 is formed over and electrically coupled to the second electrode layer 22. In some embodiments, a third contact 53 is formed over and electrically coupled to the semiconductor device 40. In some embodiments, the first contact 51, the second contact 52 and the third contact 53 extend through the oxide layer 41 and the interlayer dielectric 103. In some embodiments, the semiconductor structure 100a is completed.

One aspect of this disclosure relates to a semiconductor structure. The semiconductor structure includes a substrate having a first surface, a capacitor structure disposed within the substrate and having a bottom portion and a sidewall portion disposed over and coupled to the bottom portion, a first isolation layer disposed over the capacitor structure and within the substrate, and a semiconductor device disposed over the first isolation layer and including an oxide layer disposed over the first surface. The first isolation layer is enclosed by the oxide layer and the capacitor structure, at least a portion of the semiconductor device is surrounded by the sidewall portion of the capacitor structure, and the semiconductor device is separated from the capacitor structure.

One aspect of this disclosure relates to a semiconductor structure. The semiconductor structure includes a substrate having a surface, and a capacitor structure disposed within the substrate and having a bottom portion, a sidewall portion disposed over and coupled to the bottom portion, and an upper portion coupled to the sidewall portion and exposed through the surface. The semiconductor structure further includes a semiconductor device disposed over and separated from the capacitor structure. The sidewall portion is disposed between the bottom portion and the upper portion, and at least a portion of the semiconductor device is surrounded by the sidewall portion of the capacitor structure from a plan view.

An aspect of this disclosure relates to a method of manufacturing a semiconductor structure. The method includes providing a substrate having a surface; forming a recess in the substrate on the surface; forming a capacitor structure within and conformal to the recess; forming a first isolation layer in the recess and over the capacitor structure; disposing a semiconductor material layer in the recess and over the first isolation layer; and forming a semiconductor device over the semiconductor material layer. At least a portion of the semiconductor device is surrounded by the capacitor structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a capacitor structure disposed within the substrate and having a bottom portion and a sidewall portion disposed over and coupled to the bottom portion;
a first isolation layer disposed over the capacitor structure and within the substrate; and
a semiconductor device disposed over the first isolation layer and including an oxide layer disposed over a first surface of the substrate;
wherein the first isolation layer is enclosed by the oxide layer and the capacitor structure, at least a portion of the semiconductor device is surrounded by the sidewall portion of the capacitor structure, and the semiconductor device is separated from the capacitor structure.

2. The semiconductor structure of claim 1, wherein the capacitor structure further includes an upper portion coupled to the sidewall portion, the sidewall portion is disposed between the bottom portion and the upper portion, and the upper portion is in contact with the oxide layer.

3. The semiconductor structure of claim 2, wherein the upper portion extends from the sidewall portion and away from the semiconductor device.

4. The semiconductor structure of claim 1, wherein an angle between the bottom portion and the sidewall portion is greater than 90°.

5. The semiconductor structure of claim 1, further comprising:
a semiconductor material layer disposed between the first isolation layer and the semiconductor device.

6. The semiconductor structure of claim 1, further comprising:
a second isolation layer disposed under the capacitor structure,
wherein the capacitor structure is disposed between the first isolation layer and the second isolation layer.

7. The semiconductor structure of claim 1, wherein the capacitor structure includes a first electrode layer, a second electrode layer over the first electrode layer, and a dielectric between the first electrode layer and the second electrode layer.

8. The semiconductor structure of claim 7, further comprising:
a first contact electrically connected to the first electrode layer; and
a second contact electrically connected to the second electrode layer,
wherein the first contact and the second contact extend through the oxide layer.

9. The semiconductor structure of claim 8, further comprising:
an isolation structure coupled to the first electrode layer and extending through the dielectric and the second electrode layer,
wherein the isolation structure surrounds the first contact.

10. A semiconductor structure, comprising:
a substrate having a surface;
a capacitor structure disposed within the substrate and having a bottom portion, a sidewall portion disposed over and coupled to the bottom portion, and an upper portion coupled to the sidewall portion and exposed through the surface; and
a semiconductor device disposed over and separated from the capacitor structure;
wherein the sidewall portion is disposed between the bottom portion and the upper portion, and at least a portion of the semiconductor device is surrounded by the sidewall portion of the capacitor structure from a plan view.

11. The semiconductor structure of claim 10, further comprising:
a first isolation layer disposed under the capacitor structure; and
a second isolation layer disposed over the capacitor structure and between the capacitor structure and the semiconductor device,
wherein the capacitor structure is disposed between the first isolation layer and the second isolation layer.

12. The semiconductor structure of claim 10, wherein the capacitor structure comprises a first electrode layer and a second electrode layer separated from the first electrode layer, and the first electrode layer and the second electrode layer comprise metal silicide.

13. The semiconductor structure of claim 10, further comprising:
a semiconductor material layer disposed between the capacitor structure and the semiconductor device,
wherein the capacitor structure surrounds the semiconductor material layer from the plan view, and the semiconductor material layer surrounds the portion of the semiconductor device from the plan view.

14. A method of manufacturing a semiconductor structure, comprising:
providing a substrate having a surface;
forming a recess in the substrate on the surface;
forming a capacitor structure within and conformal to the recess;
forming a first isolation layer in the recess and over the capacitor structure;
disposing a semiconductor material layer in the recess and over the first isolation layer; and
forming a semiconductor device over the semiconductor material layer,
wherein at least a portion of the semiconductor device is surrounded by the capacitor structure.

15. The method of claim 14, further comprising:
planarizing the semiconductor material layer, the capacitor structure and the substrate before the formation of the semiconductor device,
wherein a top surface of the semiconductor material layer is coplanar with the surface of the substrate.

16. The method of claim 14, further comprising:
forming a second isolation layer in the recess,
wherein the capacitor structure is formed between the second isolation layer and the first isolation layer.

17. The method of claim 14, wherein the formation of the capacitor structure includes:
forming a first doped layer in the recess;
forming a second doped layer on the first doped layer;
forming a third doped layer over the second doped layer; and
annealing the substrate to transfer the first doped layer to a first electrode layer, the second doped layer to a dielectric, and the third doped layer to a second electrode layer.

18. The method of claim 14, further comprising:
forming a first isolation structure surrounded by the capacitor structure;
forming a second isolation structure coupled to the capacitor structure; and
electrically coupling a first contact to the capacitor structure,
wherein the first isolation structure is disposed between the capacitor structure and the semiconductor device, and a portion of the first contact is surrounded by the second isolation structure.

19. The method of claim 14, wherein the formation of the semiconductor device includes disposing an oxide layer over the capacitor structure, the first isolation layer, the semiconductor material layer and the surface of the substrate.

20. The method of claim 14, wherein the formation of the capacitor structure includes:
forming a bottom portion within the recess; and
forming a sidewall portion disposed over and coupled to the bottom portion within the recess,
wherein the bottom portion and the sidewall portion are formed simultaneously.
